(19) United States
(12) Patent Application Publication
(10) Pub. No.: US 2007/0102745 A1
(43) Pub. Date: May 10, 2007

(54) CAPACITOR STRUCTURE

(76) Inventors: Tsun-Lai Hsu, Hsinchu Hsien (TW); Albert Kuo Huei Yen, San Jose, CA (US); Wei-Liang Chen, Keelung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,938

(22) Filed: Nov. 4, 2005

(51) Int. Cl. H01L 27/108; H01L 29/94; H01L 29/76; H01L 31/119

(52) U.S. Cl. 257/303

(57) ABSTRACT

A capacitor structure is described, including a first capacitor and a second capacitor. The first capacitor includes a first electrode, a second electrode and a first insulating layer, wherein the second electrode is disposed under the first electrode and the first insulating layer between the first electrode and the second electrode. The second capacitor is disposed under the first capacitor and coupled thereto in parallel. The second capacitor includes multiple patterned metal layers and via plugs that constitute a third electrode and a fourth electrode, and a second insulating layer. The patterned metal layers are stacked in the second insulating layer and connected by the via plugs, wherein each patterned metal layer includes a portion of the third electrode and a portion of the fourth electrode that are separated by the second insulating layer.

### BACKGROUND OF THE INVENTION

1. Field of the Invention

The present invention relates to an IC device structure. More particularly, the present invention relates to a capacitor structure in an integrated circuit.

2. Description of the Related Art

With the increase in integration degree of integrated circuit, the dimensions of IC devices including capacitors are reduced, so is the capacitance of capacitor. When the semiconductor process advances into deep sub-micron generations, the capacitance of capacitor is so reduced that some requirements may not be satisfied.

There are three ways to increase the capacitance of capacitor in IC design. The first one is to decrease the thickness of the capacitor insulator, but the uniformity and stability of the insulator are difficult to control in this way. The second one is to increase the surface area of the electrodes, but the corresponding fabricating process is quite complicated in this way decreasing the throughput. The third one is to form the capacitor insulator from a high-K dielectric material.

The capacitors in integrated circuits are generally divided into three categories, i.e., metal-insulator-metal (MIM) capacitors, metal line to metal line (MOM) capacitors and metal-insulator-silicon (MIS) capacitors. MIM and MOM capacitors are widely adopted in deep sub-micron IC, but their unit-area capacitances are low. Though the unit-area capacitance can be much increased by forming the insulator from a high-K dielectric material, the reliability of high-K insulator is usually low.

Moreover, to match the capacitor region with other device regions in height for easy planarization, a dummy metal is usually disposed under a capacitor. However, such a design makes the capacitance matching and the yield worse.

### SUMMARY OF THE INVENTION

In view of the foregoing, this invention provides a capacitor structure that has a larger unit-area capacitance.

This invention also aims to provide a capacitor structure without a dummy metal disposed under the capacitor, so as to prevent the capacitance matching and the yield from being worsened.

A capacitor structure of this invention includes a first capacitor and a second capacitor. The first capacitor includes a first electrode, a second electrode under the first electrode, and a first insulating layer between the first and the second electrodes. The second capacitor is disposed under the first capacitor and coupled thereto in parallel, including a second insulating layer, and multiple patterned metal layers and via plugs that constitute a third electrode and a fourth electrode. The patterned metal layers are stacked in the second insulating layer and connected by the via plugs, wherein each patterned metal layer includes a portion of the third electrode and a portion of the fourth electrode that are separated by the second insulating layer.

In the above capacitor structure, each patterned metal layer may include two comb-like metal patterns respectively corresponding to a portion of the third electrode and a portion of the fourth electrode, wherein the comb-teeth portions of one comb-like metal pattern and those of the other comb-like metal pattern are arranged alternately to maximize the capacitance.

The above capacitor structure may further include a third capacitor under the second capacitor. The third capacitor is coupled to the first and the second capacitors in parallel, and includes a doped poly-Si layer, a metal layer over the doped poly-Si layer and a third insulating layer between the doped poly-Si layer and the metal layer.

In addition, the first insulating layer may be a composite dielectric layer, which can be a silicon oxide/silicon nitride/silicon oxide (ONO) layer. The material of the first electrode may be a metal, and that of the second electrode may also be a metal.

Another capacitor structure of this invention also includes a first and a second capacitors. The first capacitor includes a first electrode, a second electrode under the first one and a first insulating layer between the first and the second electrodes. The second capacitor is disposed under the first capacitor and coupled thereto in parallel, including a doped poly-Si layer, a metal layer over the doped poly-Si layer and a second insulating layer between the doped poly-Si layer and the metal layer. The materials of the first insulating layer and the electrodes may be the same as those mentioned above.

Still another capacitor structure of this invention includes a first capacitor and a second capacitor. The first capacitor includes a first insulating layer, and multiple patterned metal layers and via plugs that constitute a first electrode and a second electrode. The patterned metal layers are stacked in the first insulating layer and connected by the via plugs, wherein each patterned metal layer includes a portion of the first electrode and a portion of the second electrode that are separated by the first insulating layer. The second capacitor is disposed under the first one and coupled thereto in parallel, including a doped poly-Si layer, a metal layer over the doped poly-Si layer and a second insulating layer between the doped poly-Si layer and the metal layer. Each patterned metal layer may include two comb-like metal patterns as above.

Since the capacitor structure of this invention includes two or all of three types of capacitors including MIM, MOM and MIS capacitors and the two or three capacitors are coupled in parallel, the unit-area capacitance is greatly increased. Moreover, since one or two capacitors are disposed under the MIM capacitor in the capacitor structure, it is not necessary to form a dummy metal under the MIM capacitor for easy planarization, so that the capacitance matching and the yield are not worsened.

It is to be understood that both the foregoing general description and the following detailed description are exemplary, and are intended to provide further explanation of the invention as claimed.

### BRIEF DESCRIPTION OF THE DRAWINGS

FIG. 1 illustrates, in a cross-sectional view, a capacitor structure according to an embodiment of this invention, and

FIG. 2 illustrates a top view of the MOM capacitor in the capacitor structure of FIG. 1, wherein the cross-section is made along line I-I′.

FIGS. 3-5 illustrate, in a cross-sectional view, three different capacitor structures according to three more embodiments of this invention.

### DESCRIPTION OF THE PREFERRED EMBODIMENTS

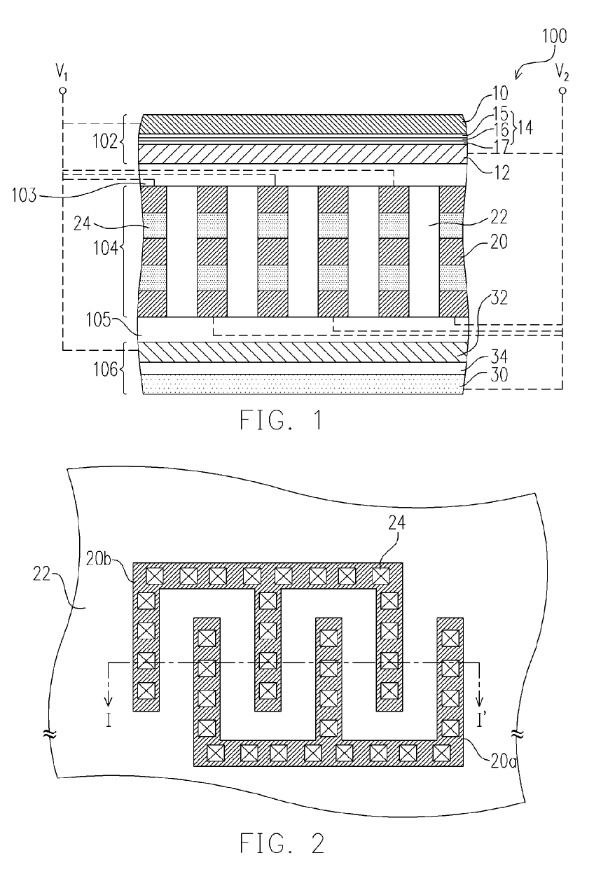

Referring to FIG. 1, the capacitor structure 100 includes a MIM capacitor 102, a MOM capacitor 104 and a MIS capacitor 106, which three are coupled in parallel. The MIM capacitor 102 includes a first electrode 10, a second electrode 12 under the first electrode 10 and an insulating layer 14 between the two electrodes 10 and 12, wherein the first or second electrode 10 or 12 may be formed from a metal or any other suitable conductive material. The insulating layer 14 may be a composite dielectric layer, such as an ONO layer consisting of a top SiO layer 15, a SiN layer 16 and a bottom SiO layer 17. In other embodiments, the insulating layer 14 can be a single SiO layer.

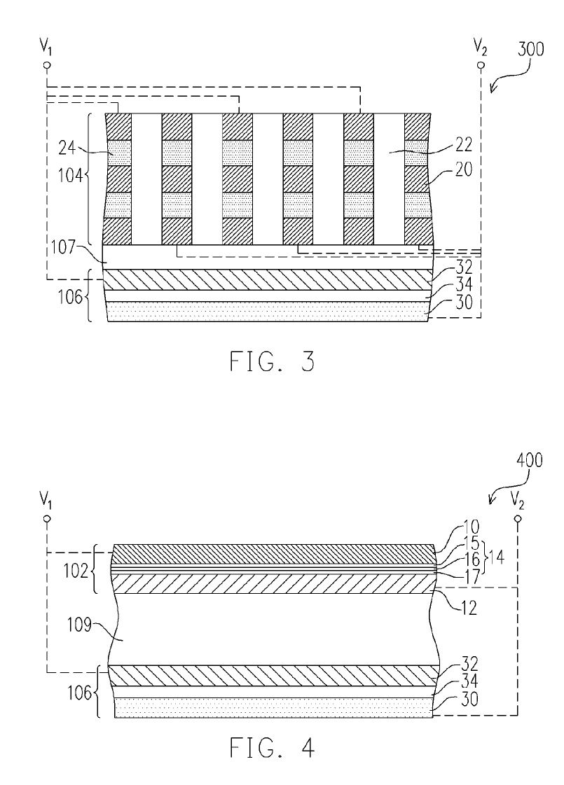

Referring to FIGS. 1 and 2, the MOM capacitor 104 is disposed under the MIM capacitor 102, including an insulating layer 22, and multiple patterned metal layers 20 and via plugs 24 that constitute a third electrode and a fourth electrode. The patterned metal layers 20 are stacked in the insulating layer 22 and connected by the via plugs 24, wherein each patterned metal layer 20 includes a portion of the third electrode and a portion of the fourth electrode.

For example, each patterned metal layer 20 may include two comb-like metal patterns 20a and 20b that are separate by the insulating layer 22, wherein the comb-like metal pattern 20a is a portion of the third electrode, and the comb-like metal pattern 20b is a portion of the fourth electrode. The comb-teeth portions of the comb-like metal pattern 20a and those of the comb-like metal pattern 20b are arranged alternately, so that the capacitance between 20a and 20b is maximized. Moreover, since the via plugs 24 connecting the two comb-like metal patterns 20a in two adjacent patterned metal layers 20 and those connecting the two comb-like metal patterns 20b in the two patterned metal layers 20 are adjacent, electrical capacitance can be provided between the two groups of via plugs 24. Therefore, the unit-area capacitance can be increased greatly.

It is particularly noted that the number of patterned metal layers 20 in the MOM capacitor 104 is not restricted to three, but can be four or more according to the requirements in the fabricating process and/or subsequent planarization.

Referring to FIG. 1 again, the MIS capacitor 106 is disposed under the MOM capacitor 104, including a doped poly-Si layer 30, a metal layer 32 over the doped poly-Si layer 30 and an insulating layer 34 between the doped poly-Si layer 30 and the metal layer 32. The material of the insulating layer 34 may be silicon oxide or any other suitable material. In addition, a dielectric layer 103 can be disposed between the MIM capacitor 102 and the MOM capacitor 104 and another dielectric layer 105 between the MOM capacitor 104 and the MIS capacitor 106 to separate the three capacitors. The material of the dielectric layer 103 or 105 may be silicon oxide, for example.

Moreover, a guard ring (not shown) made of conductive material can be formed around the capacitor structure to isolate the same from other devices, so as to prevent the operation thereof from being disturbed by the noises generated by other devices.

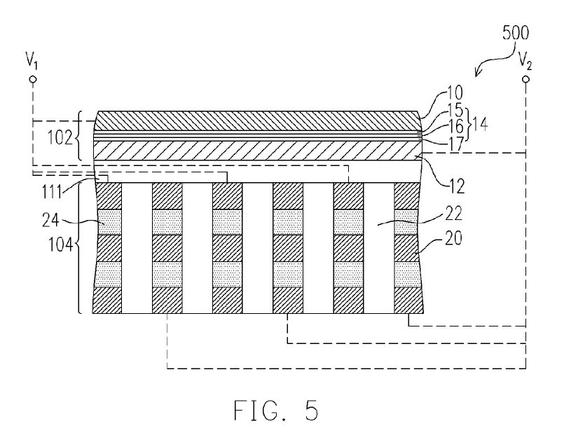

FIGS. 3-5 illustrate, in a cross-sectional view, three different capacitor structures according to three more embodiments of this invention.

Referring to FIG. 3, the capacitor structure 300 is different from the capacitor structure 100 of FIG. 1 mainly in not including a MIM capacitor (102). In the capacitor structure 300, the MOM capacitor 104 and the MIS capacitor 106 are coupled in parallel and are separated by a dielectric layer 107. Similarly, the number of patterned metal layers 20 in the MOM capacitor 104 can be four or more according to the requirements in the fabricating process and/or subsequent planarization.

Referring to FIG. 4, the capacitor structure 400 is different from the capacitor structure 100 of FIG. 1 mainly in not including a MOM capacitor (104). In the capacitor structure 400, the MIM capacitor 102 and the MIS capacitor 106 are coupled in parallel and are separated by a dielectric layer 109.

Referring to FIG. 5, the capacitor structure 500 is different from the capacitor structure 100 of FIG. 1 mainly in not including a MIS capacitor (106). In the capacitor structure 500, the MIM capacitor 102 and the MOM capacitor 104 are coupled in parallel and are separated by a dielectric layer 111. Similarly, the number of patterned metal layers 20 in the MOM capacitor 104 can be four or more according to the requirements in the fabricating process and/or subsequent planarization.

As mentioned above, the capacitor structure of this invention includes two or all of three types of capacitors including MIM, MOM and MIS capacitors, and the two or three capacitors are coupled in parallel. Therefore, the unit-area capacitance can be greatly increased. Moreover, since one or two capacitors are disposed under the MIM capacitor in the capacitor structure, it is not necessary to dispose a dummy metal under the MIM capacitor for easy planarization. Therefore, the capacitance matching and the yield are not worsened.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A capacitor structure, comprising:
a first capacitor, comprising:
a first electrode;
a second electrode under the first electrode; and
a first insulating layer between the first and the second electrodes to electrically isolate the first and second electrodes; and
a second capacitor, disposed under the first capacitor and coupled thereto in parallel, comprising;
a second insulating layer; and
a plurality of patterned metal layers and via plugs, constituting a third electrode and a fourth electrode, wherein the patterned metal layers are stacked in the second insulating layer and connected by the via plugs, and each patterned metal layer includes a portion of the third electrode and a portion of the fourth electrode that are separated by the second insulating layer.

2. The capacitor structure of claim 1, wherein each patterned metal layer includes two comb-like metal patterns respectively corresponding to a portion of the third electrode and a portion of the fourth electrode, and comb-teeth portions of one comb-like metal pattern and comb-teeth portions of the other comb-like metal pattern are arranged alternately.

3. The capacitor structure of claim 1, further comprising a third capacitor under the second capacitor, the third capacitor being coupled to the first and the second capacitors in parallel and comprising:
a doped polysilicon layer;
a metal layer over the doped polysilicon layer; and
a third insulating layer between the doped polysilicon layer and the metal layer.

4. The capacitor structure of claim 1, wherein the first insulating layer comprises a composite dielectric layer.

5. The capacitor structure of claim 4, wherein the composite dielectric layer comprises an ONO layer.

6. The capacitor structure of claim 1, wherein the first electrode comprises metal.

7. The capacitor structure of claim 1, wherein the second electrode comprises metal.

8-14. (canceled)
